(19) United States
(12) Patent Application Publication
(10) Pub. No.: US 2024/0069092 A1
(43) Pub. Date: Feb. 29, 2024

(54) ELECTRONIC DEVICE AND IMAGE FORMING APPARATUS

(71) Applicants: Kohhei Nagasawa, KANAGAWA (JP); Kohya Etoh, KANAGAWA (JP)

(72) Inventors: Kohhei Nagasawa, KANAGAWA (JP); Kohya Etoh, KANAGAWA (JP)

(73) Assignee: Ricoh Company, Ltd., Tokyo (JP)

(21) Appl. No.: 18/449,923

(22) Filed: Aug. 15, 2023

(30) Foreign Application Priority Data
Aug. 31, 2022 (JP) 2022-138041

(51) Int. Cl. G01R 31/28; G05F 1/56; G06K 15/00

(52) U.S. Cl. CPC G01R 31/2843; G05F 1/56; G06K 15/408

(57) ABSTRACT

An electronic device includes: a voltage divider circuit including a plurality of first resistors connected in series between a first node and a second node, and a plurality of second resistors connected in parallel between the second node and a ground line; and a voltage level detection circuit connected to the second node and to detect a voltage level of a divisional voltage generated at the second node.

### CROSS-REFERENCE TO RELATED APPLICATIONS

This patent application is based on and claims priority pursuant to 35 U.S.C. § 119(a) to Japanese Patent Application No. 2022-138041, filed on Aug. 31, 2022, in the Japan Patent Office, the entire disclosure of which is hereby incorporated by reference herein.

### BACKGROUND

### Technical Field

The present disclosure relates to an electronic device and an image forming apparatus.

### Related Art

There is a technique of determining an occurrence cause of a motor error in accordance with a combination of voltages obtained by voltage divider circuits connected to respective ends of a fuse provided in a power supply line of a motor driver element of a drive motor.

There is a technique of determining whether either a temperature detection switch or a temperature fuse is disconnected in accordance with a combination of voltages obtained by voltage divider circuits connected to respective ground sides of the temperature detection switch and the temperature fuse connected in series in a power supply line. For example, each of the voltage divider circuits includes a resistor disposed between a power supply side and an analog port of a microcomputer and a pair of resistors disposed in parallel between the analog port of the microcomputer and a ground side.

### SUMMARY

According to an embodiment of the present disclosure, an electronic device includes a voltage divider circuit and a voltage level detection circuit. The voltage divider circuit includes a plurality of first resistors and a plurality of second resistors. The plurality of first resistors are connected in series between a first node and a second node. The plurality of second resistors are connected in parallel between the second node and a ground line. The voltage level detection circuit is connected to the second node, and detects a voltage level of a divisional voltage generated at the second node.

According to another embodiment of the present disclosure, an image forming apparatus includes the electronic device described above and an image forming device that forms an image.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a block diagram illustrating an example of an electronic device according to one embodiment of the present disclosure;

FIG. 2 is an explanatory diagram illustrating an example of an operation of the electronic device illustrated in FIG. 1;

FIG. 3 is an explanatory diagram illustrating an example of an input voltage to an analog-to-digital converter (ADC) in response to a fault in a voltage divider circuit illustrated in FIG. 1;

FIG. 4 is an explanatory diagram illustrating an example in which an anomaly detection device illustrated in FIG. 1 detects a fault in the electronic device;

FIG. 5 is a block diagram illustrating an example of an electronic device according to another embodiment of the present disclosure;

FIG. 6 is an explanatory diagram illustrating an example in which an anomaly detection device illustrated in FIG. 5 detects a fault in the electronic device;

FIG. 7 is a block diagram illustrating an example of an electronic device according to still another embodiment of the present disclosure;

FIG. 8 is a block diagram illustrating an example of another electronic device;

FIG. 9 is an explanatory diagram illustrating an example in which an anomaly detection device illustrated in FIG. 8 detects a fault in the electronic device; and

FIG. 10 is a general arrangement diagram illustrating an example of an image forming apparatus in which the electronic device illustrated in FIG. 1, FIG. 5, or FIG. 7 is installed.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Embodiments will be described below with reference to the drawings. In the description below, the same reference signs as voltage names are used for respective voltage lines through which the respective voltages are transmitted, and the same reference signs as signal names are used for respective signal lines through which the respective signals are transmitted. Throughout the drawings, identical or similar components are denoted by identical or similar reference signs, and redundant description is omitted in some cases.

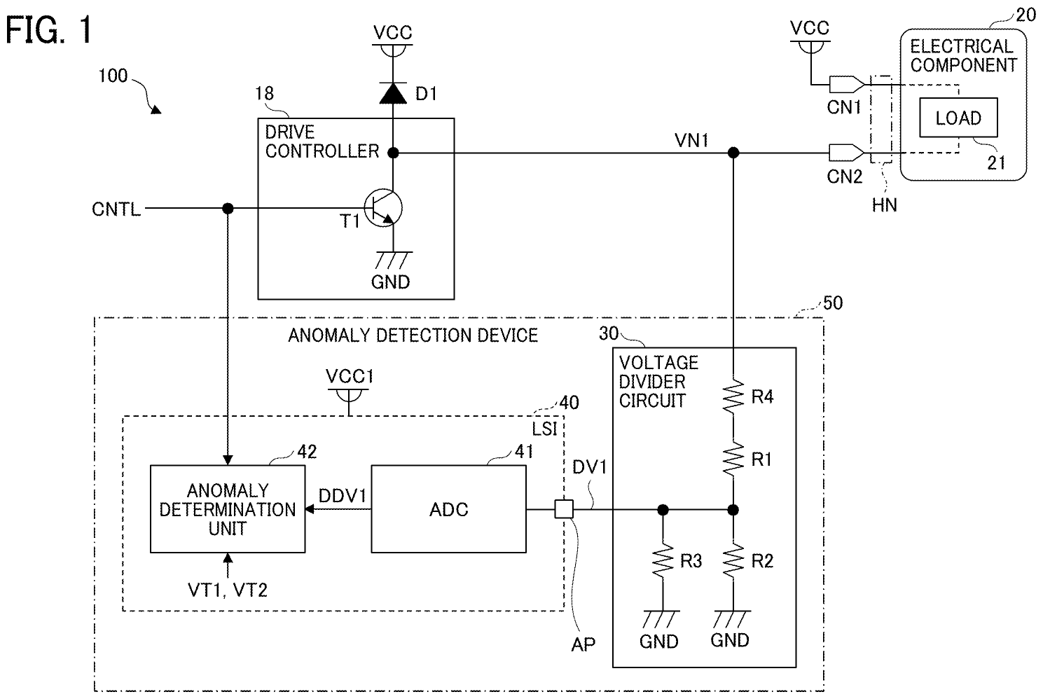

FIG. 1 is a block diagram illustrating an example of an electronic device according to one embodiment of the present disclosure. An electronic device 100 illustrated in FIG. 1 is installed in, for example, an image forming apparatus such as a digital multi-function printer, an image forming apparatus having a single function such as a scanner, a printer, or a fax machine, or a business machine such as a projector or an electronic whiteboard. The electronic device 100 functions as part of these apparatuses.

The electronic device 100 includes a drive controller 18 including a drive transistor T1, an electrical component 20 including a load 21, and an anomaly detection device 50. The anomaly detection device 50 includes a voltage divider circuit 30 and a large-scale integration (LSI) 40. The LSI 40 includes an analog-to-digital converter (ADC) 41 and an anomaly determination unit 42. The LSI 40 receives a power supply voltage VCC1 to operate. The power supply voltage VCC1 is an example of a first power supply voltage.

The drive transistor T1 of the drive controller 18 has a base connected to a control signal line CNTL, a collector connected to a detection node VN1 for voltage, and an emitter connected to a ground line GND. The detection node VN1 is connected to an anode of a diode D1. The diode D1 has a cathode connected to a power supply line VCC that is supplied with a power supply voltage VCC which is a drive voltage of the electrical component 20. The detection node VN1 is an example of a first node. The power supply voltage VCC is an example of a second power supply voltage.

When a control signal CNTL (base voltage) is at a high level, the drive transistor T1 turns on and electrically connects the detection node VN1 to the ground line GND. This sets the detection node VN1 to have a low-level voltage. When the control signal CNTL is at a low level, the drive transistor T1 turns off and electrically disconnects the detection node VN1 from the ground line GND.

The load 21 of the electrical component 20 has a power supply terminal connected to the power supply line VCC through a connector CN1. The load 21 of the electrical component 20 has a ground terminal connected to the detection node NV1 through a connector CN2. The connectors CN1 and CN2 are connected to the electrical component 20 through a harness HN. The connector CN1 is an example of a first connection part, and the connector CN2 is an example of a second connection part.

The load 21 is, for example, a solenoid, a motor, or a fan, and includes an inductive load. The electrical component 20 operates in accordance with a current flowing through the inductive load. When the drive transistor T1 turns off in response to the control signal CNTL of the low level, the current flowing through the inductive load sets the detection node VN1 to have a high-level voltage (substantially equal to the power supply voltage VCC).

The voltage divider circuit 30 includes resistors R4 and R1 connected in series between the detection node VN1 and a voltage dividing node DV1, and resistors R2 and R3 connected in parallel between the voltage dividing node DV1 and the ground line GND. Each of the resistors R4 and R1 is an example of a first resistor. Each of the resistors R2 and R3 is an example of a second resistor. The voltage dividing node DV1 is an example of a second node.

The voltage divider circuit 30 generates, at the voltage dividing node DV1, a divisional voltage DV1 obtained by dividing a voltage generated at the detection node VN1 with the resistors R4, R1, R2, and R3. Note that the number of resistors connected in series between the detection node VN1 and the voltage dividing node DV1 or the number of resistors connected in parallel between the voltage dividing node DV1 and the ground line GND is not limited to two and may be three or more.

The voltage dividing node DV1 is connected to an analog port AP of the LSI 40. The analog port AP is connected to an input of the ADC 41. The ADC 41 converts the divisional voltage DV1 received through the analog port AP into a digital value DDV1, and outputs the resulting digital value DDV1 to the anomaly determination unit 42.

The digital value DDV1 is a digital value corresponding to a value of the divisional voltage DV1 input to the ADC 41 and indirectly represents the voltage level at the detection node VN1. The digital value DDV1 is, but not limited to, an 8-bit value, a 10-bit value, or the like. The ADC 41 is an example of a voltage level detection circuit that detects a voltage level of the divisional voltage DV1 generated at the voltage dividing node DV1.

The anomaly determination unit 42 determines, in accordance with threshold values VT1 and VT2, a logical level (a first high level, a second high level, or a low level) of the digital value DDV1 supplied from the ADC 41.

For example, the anomaly determination unit 42 determines the low level if the digital value DDV1 is smaller than or equal to the threshold value VT1. The anomaly determination unit 42 determines the first high level if the digital value DDV1 is greater than the threshold value VT1 and is smaller than or equal to the threshold value VT2. The anomaly determination unit 42 determines the second high level if the digital value DDV1 is greater than the threshold value VT2.

The threshold value VT1 is, but not limited to, a digital value representing the divisional voltage DV1 of 2.1 V. The threshold value VT2 is, but not limited to, a digital value representing the divisional voltage DV1 of 4.0 V. The threshold value VT1 is an example of a threshold value for determining whether the digital value is the low level. To make the description simple, the description will be given below on the assumption that the threshold values VT1 and VT2 are voltage values (of 2.1 V and 4.0 V).

The anomaly determination unit 42 receives the control signal CNTL that is the base voltage of the drive transistor T1, and determines the drive state (on or off) of the drive transistor T1. The anomaly determination unit 42 detects various single faults in accordance with the drive state of the drive transistor T1 and the logical level of the digital value DDV1 determined in accordance with the threshold values VT1 and VT2, to determine whether the electronic device 100 has an anomaly. For example, the anomaly determination unit 42 detects a single fault that has occurred in the electrical component 20, the drive transistor T1, or any of the resistors R4, R1, R2, and R3 of the voltage divider circuit 30.

For example, the LSI 40 may be, but not limited to, a microcomputer or a field-programmable gate array (FPGA). If the LSI 40 is a microcomputer, the anomaly determination unit 42 may be implemented by an anomaly determination program executed by the microcomputer. Note that the LSI 40 may generate the control signal CNTL.

Expression (1) represents a resistance value Rs of a series combined resistance of the resistors R4 and R1. Expression (2) represents a resistance value Rp of a parallel combined resistance of the resistors R2 and R3. In the description below, R1, R2, R3, and R4 respectively denote resistance values of the resistors R1, R2, R3, and R4.

Rs=R1+R4 (1)

Rp=(R2×R3)/(R2+R3) (2)

The resistance values Rs and Rp are set such that conditions 1 and 2 below are met.

(Condition 1) The input voltage to the analog port AP at normal time is higher than the threshold value VT1.
(Condition 2) The input voltage to the analog port AP at the time of a fault is lower than a rated input voltage of the analog port AP (the ADC 41).

The normal time refers to a state in which a fault has occurred in none of the drive transistor T1, the connectors CN1 and CN2, the harness HN, and the resistors R1, R2, R3, and R4. The time of a fault refers to a state in which a single fault has occurred in the drive transistor T1, the connector CN1 or CN2, the harness HN, or any of the resistors R1, R2, R3, and R4.

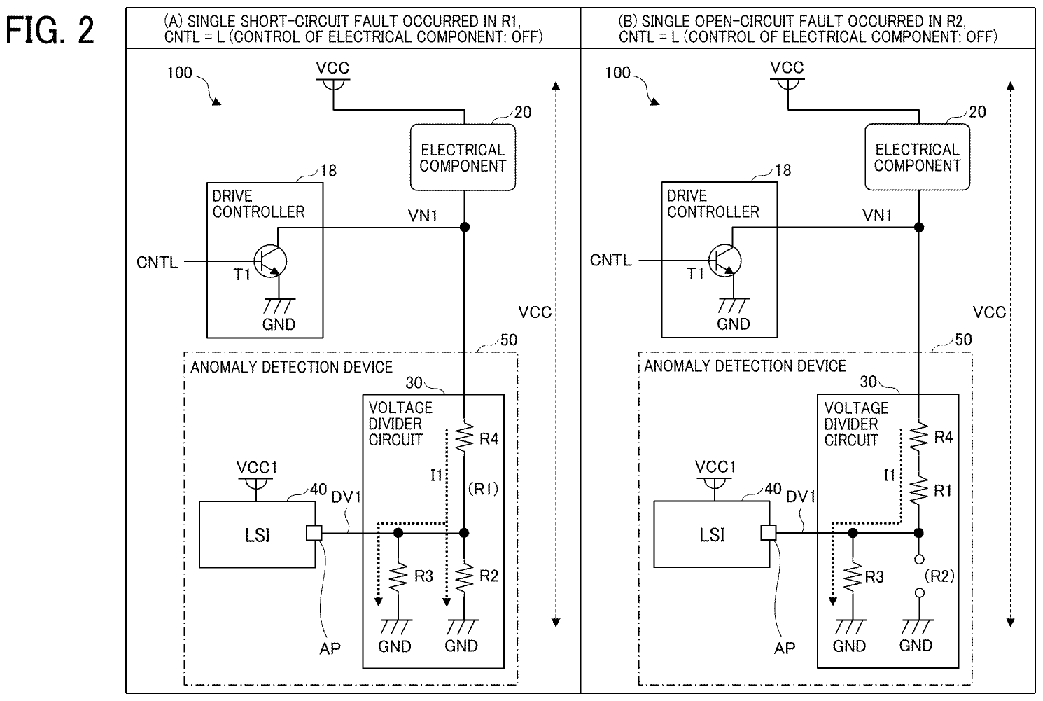

FIG. 2 is an explanatory diagram illustrating an example of an operation of the electronic device 100 illustrated in FIG. 1. Part (A) of FIG. 2 illustrates an operation in response to the occurrence of a single short-circuit fault in the resistor R1. Part (B) of FIG. 2 illustrates an operation in response to the occurrence of a single open-circuit fault in the resistor R2. In both of parts (A) and (B) of FIG. 2, the control signal CNTL is set to the low level (the drive transistor T1 is set in the off state), and thus control of the electrical component 20 is set off. In this case, the detection node VN1 which is on a high side of the voltage divider circuit 30 is set to have a voltage substantially equal to the power supply voltage VCC through the electrical component 20.

In part (A) of FIG. 2, in response to the occurrence of a single short-circuit fault in the resistor R1, the voltage divider circuit 30 causes a current Il to flow from the detection node VN1 to the ground line GND with the resistors R4, R2, and R3 to successfully generate the divisional voltage DV1. Likewise, in response to the occurrence of a single short-circuit fault in the resistor R4, the voltage divider circuit 30 successfully generates the divisional voltage DV1 with the resistors R1, R2, and R3. Thus, input of an overvoltage to the analog port AP and the input of the ADC 41 is successfully avoided.

In part (B) of FIG. 2, in response to the occurrence of a single open-circuit fault in the resistor R2, the voltage divider circuit 30 causes the current Il to flow from the detection node VN1 to the ground line GND with the resistors R4, R1, and R3 to successfully generate the divisional voltage DV1. Likewise, in response to the occurrence of a single open-circuit fault in the resistor R3, the voltage divider circuit 30 successfully generates the divisional voltage DV1 with the resistors R4, R1, and R2. Thus, input of an overvoltage to the analog port AP is successfully avoided.

Note that in response to the occurrence of a single open-circuit fault in either the resistor R4 or R1, the divisional voltage DV1 becomes substantially equal to 0 V. In response to the occurrence of a single short-circuit fault in either the resistor R2 or R3, the divisional voltage DV1 becomes substantially equal to 0 V. Thus, the voltage is not applied to the analog port AP.

In the description below, for example, the power supply voltage VCC is 24 V, the threshold value VT1 is 2.1 V, and the rated input voltage of the analog port AP is 6 V. In this case, for example, the resistance values of the resistors R4, R1, R2, and R3 are set to 51 kΩ, 51 kΩ, 24 kΩ, and 24 kΩ, respectively, such that the conditions 1 and 2 described above are met.

Expression (3) represents the divisional voltage DV1 generated by the voltage divider circuit 30.

DV1=(Rp/(Rs+Rp))×VCC (3)

The divisional voltage DV1 at the normal time when the control signal CNTL is at the low level is determined, by substituting Rs=102 kΩ and Rp=12 kΩ into Expression (3), to be about 2.5 V, which is higher than the threshold value VT1 (=2.1 V). The divisional voltage DV1 at the time of a single short-circuit fault in the resistor R1 or the resistor R4 when the control signal CNTL is at the low level is determined, by substituting Rs=51 kΩ and Rp=12 kΩ into Expression (3), to be about 4.6 V, which is lower than the rated input voltage (=6 V) of the analog port AP. The divisional voltage DV1 at the time of a single open-circuit fault in the resistor R2 or the resistor R3 when the control signal CNTL is at the low level is determined, by substituting Rs=102 kΩ and Rp=24 kΩ into Expression (3), to be about 4.6 V, which is lower than the rated input voltage (=6 V) of the analog port AP.

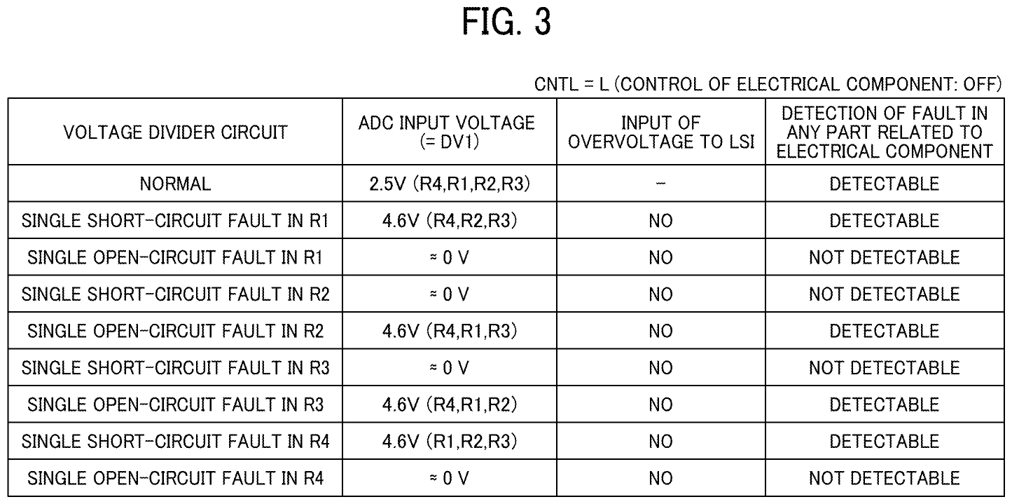

FIG. 3 is an explanatory diagram illustrating an example of an input voltage to the ADC 41 at the time of a fault in the voltage divider circuit 30 illustrated in FIG. 1. As in FIG. 2, the control signal CNTL is set to the low level, control of the electrical component 20 is set off, and the detection node VN1 which is on the high side of the voltage divider circuit 30 is set to have a voltage substantially equal to the power supply voltage VCC also in FIG. 3.

The divisional voltage DV1 which is the input voltage to the ADC 41 is determined using Expression (3) described above. At the time of a single open-circuit fault in either the resistor R1 or R4 or at the time of a single short-circuit fault in either the resistor R2 or R3, the divisional voltage DV1 is fixed substantially equal to 0 V. Thus, input of an overvoltage to the LSI 40 in response to the occurrence of a single fault in any of the resistors R1, R2, R3, and R4 is successfully avoided.

At the time of the occurrence of a single short-circuit fault in either the resistor R1 or R4 or a single open-circuit fault in either the resistor R2 or R3 in the voltage divider circuit 30, the ADC 41 successfully receives the divisional voltage DV1 (=4.6 V). In this case, the divisional voltage DV1 (=4.6 V) changes if a part related to the electrical component 20, such as the connector CN1 or CN2, the harness HN, or the drive transistor T1, has a single fault. Thus, a fault in any part related to the electrical component 20 is successfully detected also at the time of the occurrence of a single short-circuit fault in either the resistor R1 or R4 or a single open-circuit fault in either the resistor R2 or R3.

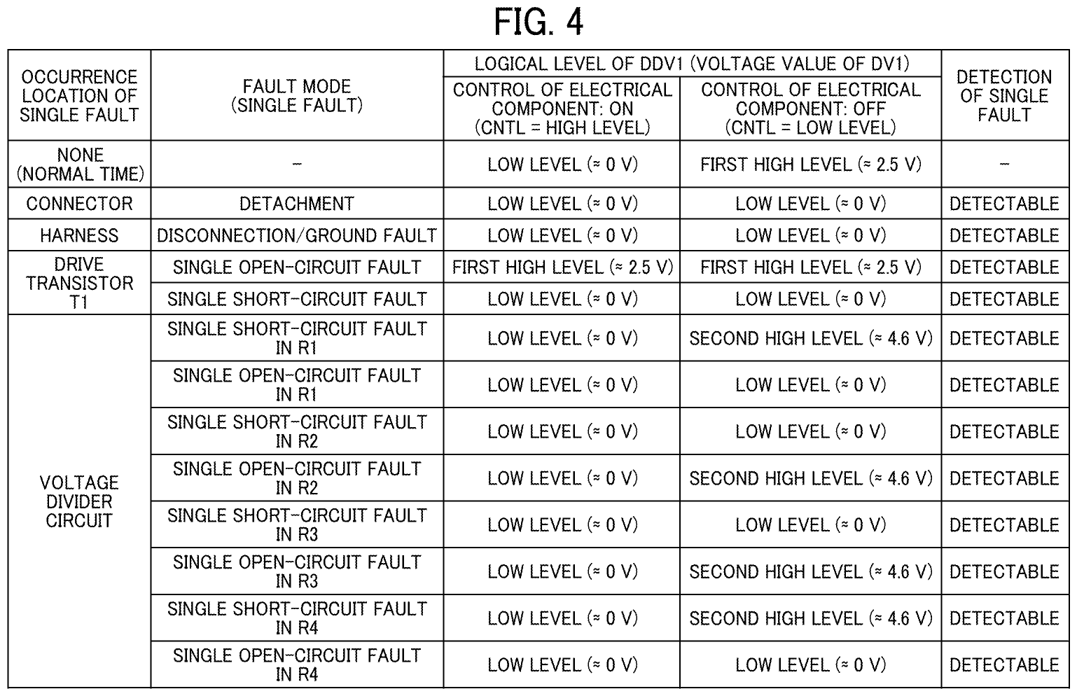

FIG. 4 is an explanatory diagram illustrating an example in which the anomaly detection device 50 illustrated in FIG. 1 detects a fault in the electronic device 100. If the control signal CNTL is at the high level at the normal time when no single fault has occurred, the divisional voltage DV1 is set substantially equal to 0 V and the digital value DDV1 is set to the low level. If the control signal CNTL is at the low level at the normal time when no single fault has occurred, the divisional voltage DV1 is set substantially equal to 2.5 V and the digital value DDV1 is set to the first high level.

The anomaly determination unit 42 detects a single fault if a combination of the logical levels of the digital value DDV1 for the high level and the low level of the control signal CNTL is different from a combination at the normal time. For example, in response to the occurrence of a single fault due to detachment of the connector CN1 or the connector CN2, or disconnection or ground fault of the harness HN, the digital value DDV1 is set to the low level different from the level at the normal time if the control signal CNTL is at the low level. This allows the anomaly detection device 50 to detect a single fault of either the connector CN1 or CN2 or the harness HN.

In response to the occurrence of a single open-circuit fault in the drive transistor T1, the digital value DDV1 is set to the first high level different from the level at the normal time if the control signal CNTL is at the high level. This allows the anomaly detection device 50 to detect a single open-circuit fault in the drive transistor T1. In response to the occurrence of a single short-circuit fault in the drive transistor T1, the digital value DDV1 is set to the low level different from the level at the normal time if the control signal CNTL is at the low level. This allows the anomaly detection device 50 to detect a single short-circuit fault in the drive transistor T1.

In response to the occurrence of a single open-circuit fault in the resistor R1 or R4 or a single short-circuit fault in the resistor R2 or R3, the digital value DDV1 is set to the low level different from the level at the normal time if the control signal CNTL is at the low level. This allows the anomaly detection device 50 to detect a single open-circuit fault in either the resistor R1 or R4 or a single short-circuit fault in either the resistor R2 or R3.

In response to the occurrence of a single short-circuit fault in the resistor R1 or R4 or a single open-circuit fault in the resistor R2 or R3, the digital value DDV1 is set to the second high level different from the level at the normal time if the control signal CNTL is at the low level. This allows the anomaly detection device 50 to detect a single short-circuit fault in either the resistor R1 or R4 or a single open-circuit fault in either the resistor R2 or R3.

As described above, in this embodiment, the voltage divider circuit 30 includes the resistors R4 and R1 connected in series between the detection node VN1 and the voltage dividing node DV1 and the resistors R2 and R3 connected in parallel between the voltage dividing node DV1 and the ground line VSS. This allows the voltage divider circuit 30 to continue to have a voltage dividing function even if a single fault occurs in any of the resistors R4, R1, R2, and R3. Thus, application of the high-level voltage (for example, the power supply voltage VCC) at the detection node VN1 to the analog port AP and the input of the ADC 41 is successfully avoided.

The resistance values of the resistors R1, R2, R3, and R4 are set to values with which a voltage lower than the rated input voltages of the analog port AP and the ADC 41 is supplied in response to the occurrence of a single fault in any of the resistors R1, R2, R3, and R4. Thus, application of an overvoltage to the ADC 41 is successfully avoided, and destruction of the LSI 40 is successfully avoided.

The anomaly determination unit 42 receives the digital value DDV1 output by the ADC 41, which receives the divisional voltage DV1 lower than the rated input voltage, and the logical level of the control signal CNTL, and determines a single fault. Thus, the anomaly determination unit 42 successfully detects a single fault in a part related to the electrical component 20 or a single fault in any of the resistors R1 to R4 if the combination of the logical levels of the digital value DDV1 for the high level and the low level of the control signal CNTL is different from the combination at the normal time as illustrated in FIG. 4.

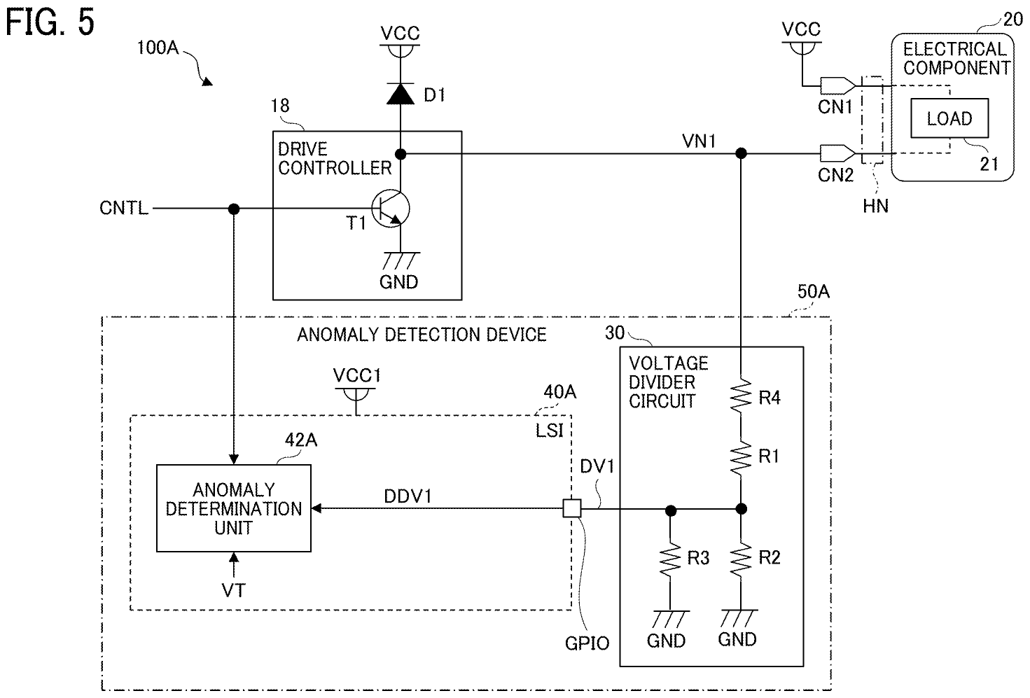

FIG. 5 is a block diagram illustrating an example of an electronic device according to another embodiment of the present disclosure. The same elements as those in FIG. 1 are denoted by the same reference signs, and detailed description is omitted. Similarly to the electronic device 100 illustrated in FIG. 1, an electronic device 100A illustrated in FIG. 5 is installed in, for example, any of various image forming apparatuses or a business machine such as a projector or an electronic whiteboard, and functions as part of these apparatuses.

The electronic device 100A has substantially the same configuration as the electronic device 100 illustrated in FIG. 1 except that the electronic device 100A includes an anomaly detection device 50A instead of the anomaly detection device 50. The anomaly detection device 50A has substantially the same configuration as the anomaly detection device 50 illustrated in FIG. 1 except that the anomaly detection device 50A includes an LSI 40A instead of the LSI 40. The LSI 40A has substantially the same configuration as the LSI 40 illustrated in FIG. 1 except that the LSI 40A includes a general-purpose input/output port GPIO and an anomaly determination unit 42A instead of the analog port AP and the anomaly determination unit 42 and does not include the ADC 41.

The general-purpose input/output port GPIO receives the divisional voltage DV1 generated by the voltage divider circuit 30, and outputs the binary digital value DDV1 to the anomaly determination unit 42A in accordance with the divisional voltage DV1. That is, the LSI 40A generates, as the digital value DDV1, a voltage level corresponding to the voltage at the detection node VN1 by using the general-purpose input/output port GPIO without using the ADC 41. The general-purpose input/output port GPIO is an example of a voltage level detection circuit that detects a voltage level corresponding to the voltage at the detection node VN1.

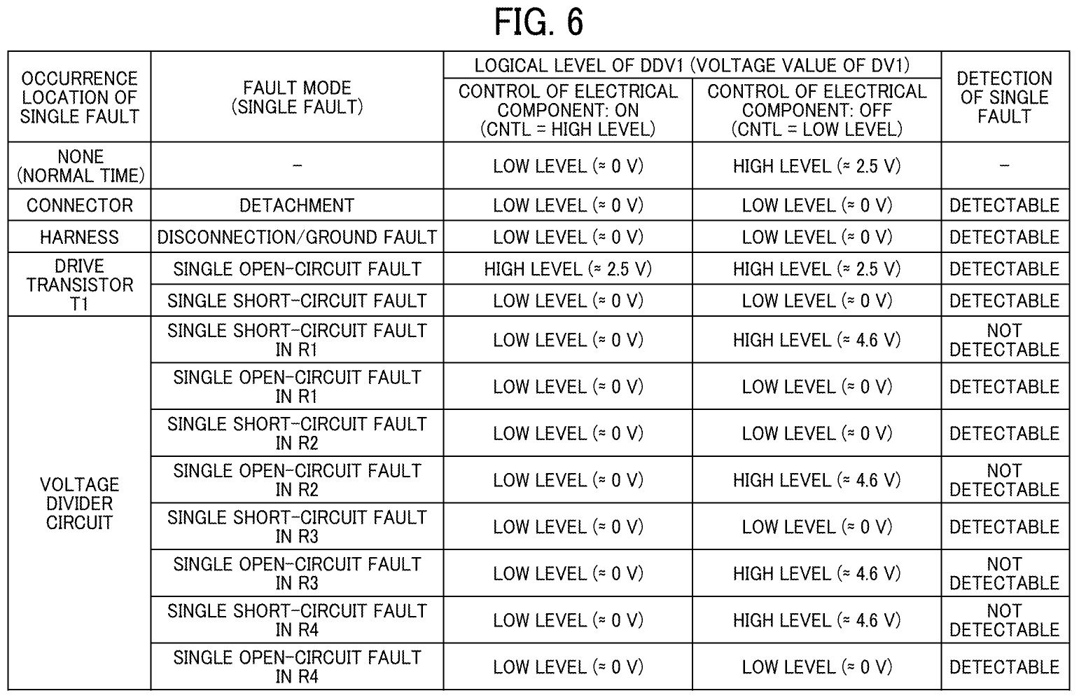

The anomaly determination unit 42A has substantially the same function as the anomaly determination unit 42 illustrated in FIG. 1 except that the digital value DDV1 used in determination of a single fault is binary and the anomaly determination unit 42A uses a single threshold value VT. An operation of the anomaly determination unit 42A will be described with reference to FIG. 6. In this embodiment, for example, the LSI 40A not including the ADC 41 and the analog port AP illustrated in FIG. 1 can be installed in the electronic device 100A. Thus, the LSI 40A that is less costly than the LSI 40 is usable, which allows a reduction in cost of the electronic device 100A.

FIG. 6 is an explanatory diagram illustrating an example in which the anomaly detection device illustrated in FIG. 5 detects a fault in the electronic device. Detailed description of the same elements as those in FIG. 4 is omitted. In this embodiment, the logical level of the digital value DDV1 input to the anomaly determination unit 42A in response to each single fault is a low level or a high level (binary). Note that the voltage level of the divisional voltage DV1 supplied to the general-purpose input/output port GPIO is the same as that in FIG. 4.

In this embodiment, the anomaly determination unit 42A compares the digital value DDV1 with the threshold value VT to determine the low level or the high level of the digital value DDV1. The anomaly determination unit 42A successfully detects a single fault if a combination of the logical levels of the digital value DDV1 for the high level and the low level of the control signal CNTL is different from the combination at the normal time.

Note that the combination of the logical levels of the digital value DDV1 for the high level and the low level of the control signal CNTL is the same as the combination at the normal time for a single short-circuit fault in either the resistor R1 or R4. Thus, the anomaly determination unit 42A fails to detect the fault. In addition, the combination of the logical levels of the digital value DDV1 for the high level and the low level of the control signal CNTL is the same as the combination at the normal time for a single open-circuit fault in either the resistor R2 or R3. Thus, the anomaly determination unit 42A fails to detect the fault. However, the anomaly determination unit 42A successfully detects a single fault due to detachment of the connector CN1 or the connector CN2, a single fault due to disconnection or ground fault of the harness HN, or a single fault of the drive transistor T1.

As described above, substantially the same advantageous effects as those of the embodiment illustrated in FIGS. 1 to 4 can be obtained also in this embodiment. For example, the anomaly determination unit 42A successfully detects a single fault in any part related to the electrical component 20, based on the divisional voltage DV1 generated by the voltage divider circuit 30 and the logical level of the control signal CNTL. In addition, the anomaly determination unit 42A successfully detects a single open-circuit fault in the resistor R1 or R4 or a single short-circuit fault in the resistor R2 or R3.

Further, in this embodiment, the LSI 40A not including the ADC 41 and the analog port AP illustrated in FIG. 1 can be installed in the electronic device 100A. Thus, the LSI 40A that is less costly than the LSI 40 is usable, which allows a reduction in cost of the electronic device 100A.

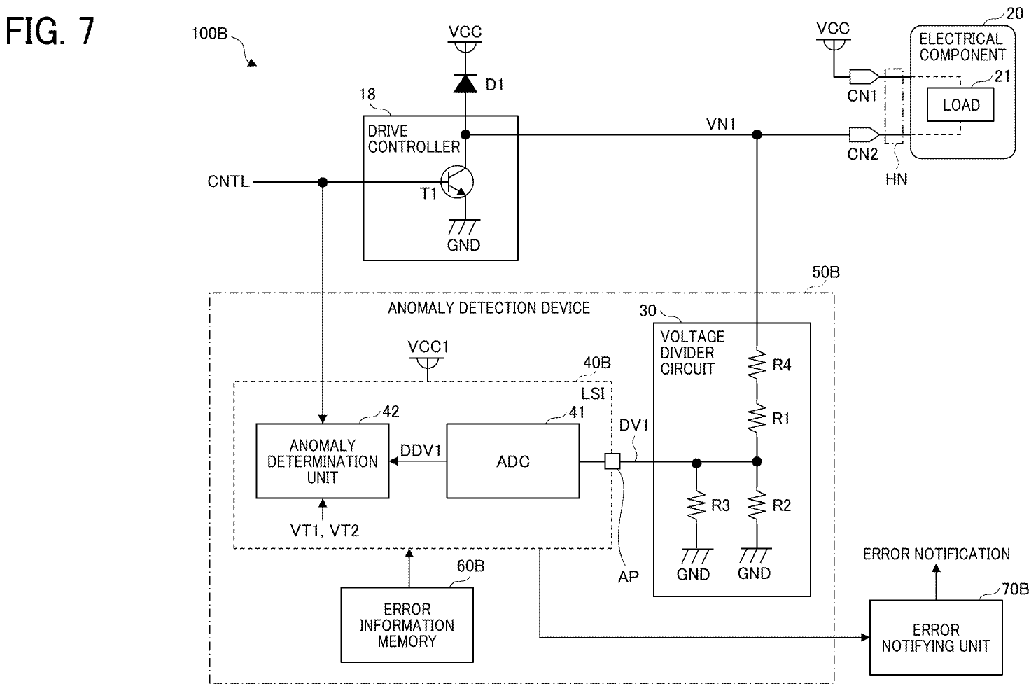

FIG. 7 is a block diagram illustrating an example of an electronic device according to still another embodiment of the present disclosure. The same elements as those in FIG. 1 are denoted by the same reference signs, and detailed description is omitted. Similarly to the electronic device 100 illustrated in FIG. 1, an electronic device 100B illustrated in FIG. 7 is installed in, for example, any of various image forming apparatuses or a business machine such as a projector or an electronic whiteboard, and functions as part of these apparatuses.

The electronic device 100B has substantially the same configuration as the electronic device 100 illustrated in FIG. 1 except that the electronic device 100B includes an anomaly detection device 50B instead of the anomaly detection device 50 and further includes an error notifying unit 70B. The anomaly detection device 50B has substantially the same configuration as the anomaly detection device 50 illustrated in FIG. 1 except that the anomaly detection device 50B includes an LSI 40B instead of the LSI 40 and further includes an error information memory 60B.

In the error information memory 60B, error information is recorded which indicates various errors that have occurred in an apparatus such as an image forming apparatus in which the electronic device 100B is installed. For example, when the electronic device 100B is installed in an image forming apparatus such as a printer, the error information includes information on a paper jam, an error of a drive motor, and so on.

The LSI 40B performs one of or both of analysis of a cause of an anomaly and prediction of the occurrence of an anomaly in the apparatus such as the image forming apparatus in which the electronic device 100B is installed, based on a single fault detected by the anomaly determination unit 42 and the error information recorded in the error information memory 60B.

The LSI 40B also outputs, to the error notifying unit 70B, error information indicating an anomaly (that is, a single fault) determined by the anomaly determination unit 42. The error notifying unit 70B is, for example, a display such as a liquid crystal monitor installed in an operation device of the electronic device 100B. The error notifying unit 70B displays the error information on the display to notify an outside entity of the occurrence of an error. Alternatively, the error notifying unit 70B is, for example, a communication device that transmits the error information to a service site of the apparatus in which the electronic device 100B is installed. That is, the error notifying unit 70B provides a notification of the anomaly determined by the anomaly determination unit 42 to outside the electronic device 100B.

As described above, substantially the same advantageous effects as those of the embodiment illustrated in FIGS. 1 to 4 can be obtained also in this embodiment. For example, the anomaly determination unit 42 successfully detects a single fault in any part related to the electrical component 20, based on the divisional voltage DV1 generated by the voltage divider circuit 30 and the logical level of the control signal CNTL. In addition, the anomaly determination unit 42 successfully detects a single open-circuit fault or a single short-circuit fault in the resistor R1, R2, R3, or R4.

Further, in this embodiment, the LSI 40B performs one of or both of analysis of a cause of an anomaly and prediction of the occurrence of an anomaly, based on a single fault detected by the anomaly determination unit 42 and the error information recorded in the error information memory 60B. The LSI 40B also outputs, to the error notifying unit 70B, the anomaly determined by the anomaly determination unit 42 to perform one of or both of display of the error information on a display and transmission of the error information to outside.

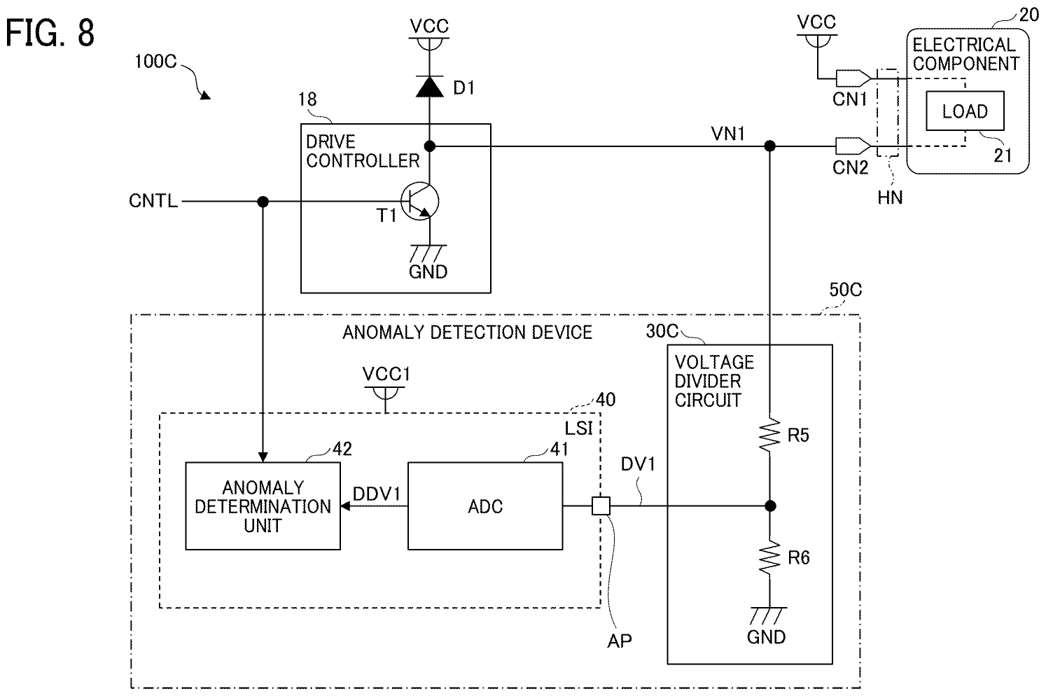

FIG. 8 is a block diagram illustrating an example of another electronic device. The same elements as those in FIG. 1 are denoted by the same reference signs, and detailed description is omitted. An electronic device 100C illustrated in FIG. 8 has substantially the same configuration as the electronic device 100 illustrated in FIG. 1 except that the electronic device 100C includes an anomaly detection device 50C instead of the anomaly detection device 50. The anomaly detection device 50C has substantially the same configuration as the anomaly detection device 50 illustrated in FIG. 1 except that the anomaly detection device 50C includes a voltage divider circuit 30C instead of the voltage divider circuit 30.

The voltage divider circuit 30C includes a resistor R5 connected between the detection node VN1 and the voltage dividing node DV1, and a resistor R6 connected between the voltage dividing node DV1 and the ground line GND. For example, the resistor R5 has, but not limited to, a resistance value of 102 kΩ, and the resistor R6 has, but not limited to, a resistance value of 12 kΩ.

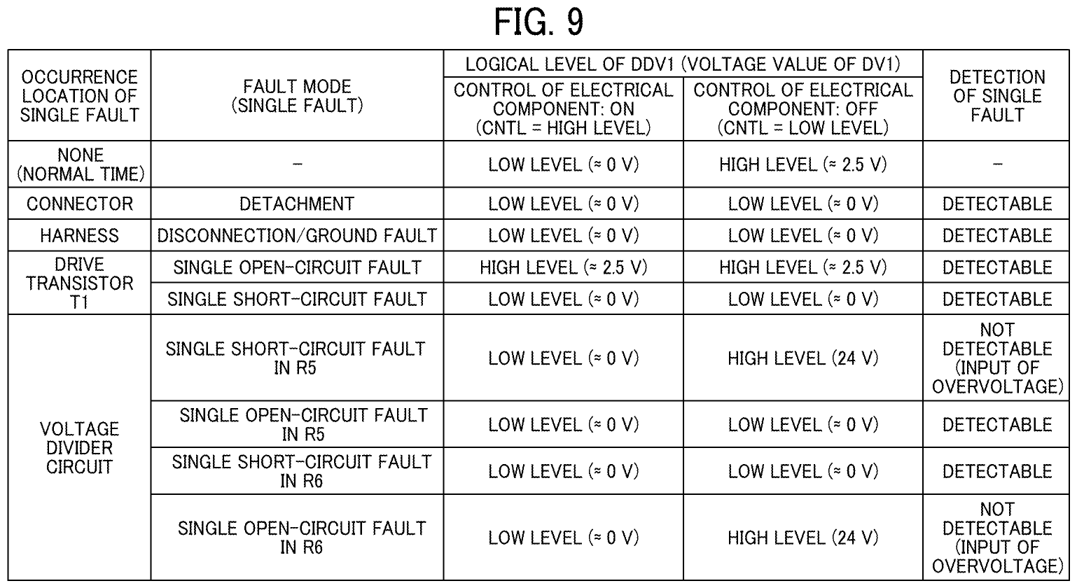

FIG. 9 is an explanatory diagram illustrating an example in which the anomaly detection device 50C illustrated in FIG. 8 detects a fault in the electronic device 100C. Detailed description of the same elements as those in FIG. 4 is omitted.

As in FIG. 4, in FIG. 9, the anomaly determination unit 42 successfully detects a single fault due to detachment of the connector CN1 or the connector CN2, a single fault due to disconnection or ground fault of the harness HN, or a single fault of the drive transistor T1. In addition, the anomaly determination unit 42 successfully detects a single open-circuit fault in the resistor R5 and a single short-circuit fault in the resistor R6.

On the other hand, in response to the occurrence of a single short-circuit fault in the resistor R5, a voltage (for example, 24 V) at the detection node VN1 exceeding the rated input voltage may be input to the analog port AP and destroy the LSI 40. In addition, in response to the occurrence of a single open-circuit fault in the resistor R6, a voltage (for example, 24 V) at the detection node VN1 exceeding the rated input voltage may be input to the analog port AP and destroy the LSI 40.

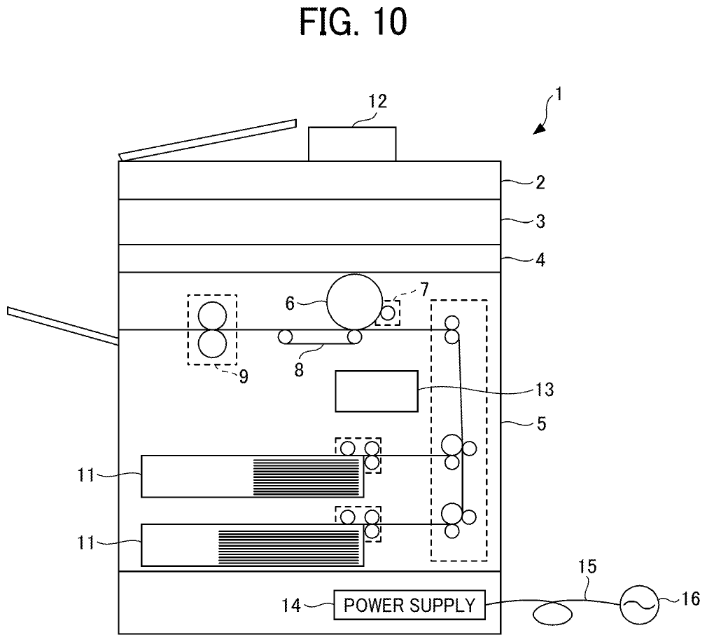

FIG. 10 is a general arrangement diagram illustrating an example of an image forming apparatus in which the electronic device 100 illustrated in FIG. 1, the electronic device 100A illustrated in FIG. 5, or the electronic device 100B illustrated in FIG. 7 is installed. An image forming apparatus 1 illustrated in FIG. 10 is, for example, a digital multi-function printer (MFP) having a copy function, a print function, a scanner function, a facsimile function, and so on.

In the image forming apparatus 1, respective operation modes for implementing the copy function, the print function, the scanner function, and the facsimile function are switchable between one another with an application switch button or the like of an operation device of the image forming apparatus 1. The image forming apparatus 1 enters a copy mode in response to selection of the copy function, enters a print mode in response to selection of the print function, enters a scanner mode in response to selection of the scanner function, and enters a facsimile mode in response to selection of the facsimile function.

In the image forming apparatus 1, an internal state switches into a normal mode or a power-save mode (power efficient mode) in accordance with the state of an internal circuit. For example, the normal mode includes an operating mode (operating state) and a standby mode (standby state).

For example, the operating mode includes a copy mode or a print mode in which an image, text data, or the like is printed on a medium such as paper. The print mode includes an operation of printing data received in the facsimile mode on a medium such as paper. The operating mode also includes a scanner mode in which an original or the like is scanned or a transmission/reception operation in the facsimile mode. The state of the internal circuit is switched in accordance with an operation on the operation device by a user of the image forming apparatus 1 or control inside the image forming apparatus 1.

For example, the image forming apparatus 1 includes an auto document feeder (ADF) 2, an image scanner unit 3, a writing unit 4, a printer unit 5, an operation device 12, a control device 13, and a power supply 14. The printer unit 5 includes a photoconductor drum 6, a developing device 7, a transport belt 8, a fixing device 9, and an accommodation space where sheet feeding trays 11 are accommodated.

For example, the control device 13 includes therein the anomaly detection device 50 illustrated in FIG. 1, the anomaly detection device 50A illustrated in FIG. 5, or the anomaly detection device 50B illustrated in FIG. 7, and the drive controller 18. The electrical component 20 illustrated in FIG. 1, FIG. 5, or FIG. 7 is, for example, any of various motors or fans provided in the printer unit 5.

The power supply 14 is connected to a commercial power supply 16 through a power supply cable 15. The power supply 14 has a function of, by using an alternating-current (AC) voltage supplied from the commercial power supply 16, generating for example an AC voltage and a direct-current (DC) voltage and supplying the AC voltage and the DC voltage to a load as electric power. Examples of the load supplied with electric power include the ADF 2, the image scanner unit 3, the writing unit 4, the printer unit 5, and the operation device 12.

The printer unit 5 creates, based on image information, a toner image to be transferred onto a medium such as paper. The printer unit 5 is an example of an image forming unit that forms an image. As an example of a procedure in which the image forming apparatus 1 forms an image, a case where the operation mode is set to the copy mode will be briefly described.

In the copy mode, a bundle of originals to be copied (a plurality of sheets of originals) are placed at the ADF 2 or an original to be copied is placed on the image scanner unit 3. In response to pressing of a start button displayed on the operation device 12, the ADF 2 feeds the originals one by one to the image scanner unit 3. The image scanner unit 3 scans image information of each of the originals sequentially fed to the image scanner unit 3 from the ADF 2 or the original placed on the image scanner unit 3. The image information obtained by the image scanner unit 3 through scanning is processed by, for example, an image processor installed in the control device 13.

The writing unit 4 converts the image information processed by the image processor into light information. The photoconductor drum 6 is evenly charged by a charger disposed at a position opposite the photoconductor drum 6, and then is exposed by laser light including the light information converted by the writing unit 4. Through the exposure, an electrostatic latent image is formed on the photoconductor drum 6. The developing device 7 develops the electrostatic latent image on the photoconductor drum 6 to form a toner image on the photoconductor drum 6. The transport belt 8 transfers the toner image onto a medium such as paper. The fixing device 9 fixes the toner image on the medium such as paper. Then, the medium such as paper having a transferred copy of the image of the original is discharged from a discharge unit.

The operation device 12 accepts various kinds of input according to operations of the user. The operation device 12 also display various kinds of information on the display thereof. The information displayed on the operation device 12 is, for example, information indicating an input operation that has been accepted, information indicating an operation state of the image forming apparatus 1, information indicating a setting state of the image forming apparatus 1, or the like. If the error notifying unit 70B illustrated in FIG. 7 has a function of displaying the error information on the display, the error notifying unit 70B may be installed in the operation device 12, for example.

The control device 13 causes a controller such as a CPU included therein to execute a control program to control operations of the entire image forming apparatus 1 such as control of the printer unit 5, control of communication, and control of input to the operation device 12. If the error notifying unit 70B illustrated in FIG. 7 has a function of a communication device that transmits the error information to a service site of the image forming apparatus 1, the error notifying unit 70B may be installed in the control device 13, for example. The control device 13 executes an image processing program or a data processing program to perform image processing or data processing and thus forms an image to be transferred onto a medium such as paper.

For example, a control circuit board of the operation device 12 receives a DC voltage from the power supply 14 and operates all the time. This allow the operation device 12 to accept various kinds of input in the power-save mode as well as the normal mode. For example, the control device 13 receives a DC voltage to operate in the normal mode, and stops operating in the power-save mode.

According to the embodiments described above, application of an overvoltage to a voltage level detection circuit that detects a level of a divisional voltage is successfully avoided even if a fault occurs in any of a plurality of resistors included in a voltage divider circuit.

For example, aspects of the present disclosure are as described below.

According to Aspect 1, an electronic device includes a voltage divider circuit and a voltage level detection circuit. The voltage divider circuit including a plurality of first resistors and a plurality of second resistors. The plurality of first resistors are connected in series between a first node and a second node. The plurality of second resistors are connected in parallel between the second node and a ground line. The voltage level detection circuit is connected to the second node, and detects a voltage level of a divisional voltage generated at the second node.

According to Aspect 2, in the electronic device of Aspect 1, the first node is set to have a high-level voltage or a low-level voltage, the voltage level detection circuit receives a first power supply voltage lower than the high-level voltage to operate, and outputs a digital value corresponding to the voltage level of the divisional voltage, the digital value is determined to be either at least one high level or a low level in accordance with at least one threshold value, and the plurality of first resistors and the plurality of second resistors have respective resistance values that are set such that the divisional voltage for the high-level voltage at the first node is between a rated input voltage of the voltage level detection circuit and a voltage corresponding to the threshold value for determining whether the digital value is the low level in a case where the plurality of first resistors and the plurality of second resistors are all normal and in a case where any of the plurality of first resistors or the plurality of second resistors has a fault.

According to Aspect 3, the electronic device of Aspect 2 further includes an electrical component, a drive transistor, and an anomaly determination circuit. The electrical component includes a load. The load is connected, through a first connection part, to a power supply line supplied with a second power supply voltage and is connected, through a second connection part, to the first node. The drive transistor sets the first node to have a voltage lower than the second power supply voltage while the drive transistor drives the load. The anomaly determination circuit determines an anomaly in any of the first connection part, the second connection part, the drive transistor, the plurality of first resistors, or the plurality of second resistors, in accordance with the voltage level determined by the voltage level detection circuit and a drive state of the drive transistor. The first node is set to have the high-level voltage in accordance with a current from the load while the drive transistor does not drive the load.

According to Aspect 4, the electronic device of Aspect 3 further includes an integrated circuit. The integrated circuit includes the voltage level detection circuit and the anomaly determination circuit. The anomaly determination circuit receives a base voltage of the drive transistor and determines the drive state of the drive transistor.

According to Aspect 5, in the electronic device of Aspect 4, the integrated circuit includes an analog port to which the divisional voltage generated at the second node is input, and the voltage level detection circuit includes an analog-to-digital converter. The analog-to-digital converter converts the divisional voltage input to the analog port into the digital value and outputs the digital value to the anomaly determination circuit.

According to Aspect 6, in the electronic device of Aspect 4, the voltage level detection circuit includes a general-purpose input/output port. The general-purpose input/output port receives the divisional voltage generated at the second node and outputs the digital value corresponding to the received divisional voltage to the anomaly determination circuit.

According to Aspect 7, the electronic device of any one of Aspects 3 to 6 further includes an error information memory. In the error information memory, error information is recorded. The error information indicates an error that has occurred in an apparatus in which the electronic device is installed. The anomaly determination circuit further performs one of or both of analysis of a cause of an anomaly and prediction of occurrence of an anomaly in the apparatus in which the electronic device is installed, based on the determined anomaly and the error information recorded in the error information memory.

According to Aspect 8, the electronic device of any one of Aspects 3 to 7 further includes an error notifying unit. The error notifying unit provides a notification of the anomaly determined by the anomaly determination circuit to outside the electronic device.

According to Aspect 9, an image forming apparatus includes the electronic device of any one of Aspects 1 to 8, and an image forming unit. The image forming unit forms an image.

While the present disclosure has been described based on each embodiment above, the present disclosure is not limited by the requirements described in the above embodiment. In this regard, the present disclosure can be modified within a scope not departing from the gist thereof, and can be appropriately implemented according to an application style thereof.

1. An electronic device comprising:
a voltage divider circuit including
a plurality of first resistors connected in series between a first node and a second node, and
a plurality of second resistors connected in parallel between the second node and a ground line; and
a voltage level detection circuit connected to the second node and to detect a voltage level of a divisional voltage generated at the second node.

2. The electronic device according to claim 1, wherein
the first node is set to have a high-level voltage or a low-level voltage,
the voltage level detection circuit is to operate according to a first power supply voltage lower than the high-level voltage, and output a digital value based on the voltage level of the divisional voltage,
the digital value being determined to be either a high level or a low level in accordance with a threshold value, and
the plurality of first resistors and the plurality of second resistors have respective resistance values that are set such that the divisional voltage when the first node is set to have the high-level voltage is between a voltage based on the threshold value and a rated input voltage of the voltage level detection circuit, each in a case where the plurality of first resistors and the plurality of second resistors are all normal and in a case where any of the plurality of first resistors or the plurality of second resistors has a fault.

3. The electronic device according to claim 2, further comprising:
an electrical component including a load, the load being connected through a first connector to a power supply line supplied with a second power supply voltage, and connected through a second connector to the first node;
a drive transistor to set the first node to have a voltage lower than the second power supply voltage during when the load is driven by the drive transistor; and
an anomaly determination circuit to determine an anomaly in any of the first connector, the second connector, the drive transistor, the plurality of first resistors, or the plurality of second resistors, in accordance with the voltage level determined by the voltage level detection circuit and a drive state of the drive transistor, wherein
the first node is set to have the high-level voltage in accordance with a current from the load during when the load is not driven by the drive transistor.

4. The electronic device according to claim 3, further comprising:
an integrated circuit including the voltage level detection circuit and the anomaly determination circuit, wherein
the anomaly determination circuit is to receive a base voltage of the drive transistor and determine the drive state of the drive transistor.

5. The electronic device according to claim 4, wherein
the integrated circuit includes an analog port to which the divisional voltage generated at the second node is input, and
the voltage level detection circuit is an analog-to-digital converter to convert the divisional voltage input to the analog port into the digital value and output the digital value to the anomaly determination circuit.

6. The electronic device according to claim 4, wherein the voltage level detection circuit is a general-purpose input/output port to receive the divisional voltage generated at the second node and output the digital value based on the received divisional voltage to the anomaly determination circuit.

7. The electronic device according to claim 3, further comprising:
an error information memory that stores error information, the error information indicating an error that has occurred in an apparatus in which the electronic device is installed, wherein
the anomaly determination circuit is to further perform at least one of analysis of a cause of an anomaly or prediction of occurrence of an anomaly, in the apparatus in which the electronic device is installed, based on the determined anomaly and the error information stored in the error information memory.

8. The electronic device according to claim 3, further comprising:
an error notifying unit configured to provide a notification of the anomaly determined by the anomaly determination circuit to an extraneous source.

9. An image forming apparatus comprising:
the electronic device according to claim 1; and
an image forming unit to form an image.

10. An image forming apparatus comprising:
the electronic device according to claim 8; and
an image forming unit to form an image.
